(19) United States
(12) Patent Application Publication
(10) Pub. No.: US 2007/0095566 A1
(43) Pub. Date: May 3, 2007

(54) Printed wiring board and printed circuit board using the same

(75) Inventor: Yoshihiro Nishida, Akishima-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/586,687

(22) Filed: Oct. 26, 2006

(30) Foreign Application Priority Data
Oct. 27, 2005 (JP) 2005-313367

(51) Int. Cl. H05K 1/11; H01R 12/04

(52) U.S. Cl. 174/262

(57) ABSTRACT

According to one embodiment, disclosed is a printed wiring board in which a plurality of pads are formed on the substrate surface, a surface conductor layer is formed around the pads, and at least one of the pads is partially in contact with the surface conductor layer.

### CROSS-REFERENCE TO RELATED APPLICATIONS

This application is based upon and claims the benefit of priority from Japanese Patent Application No. 2005-313367, filed Oct. 27, 2005, the entire contents of which are incorporated herein by reference.

### BACKGROUND

1. Field

One embodiment of the invention relates to a printed wiring board for mounting an electronic part having a plurality of solder balls, and a printed circuit board having this electronic part mounted on it.

2. Description of the Related Art

Printed circuit boards used in conventional electronic devices require small electric currents, so it is unnecessary to positively supply electric currents by forming surface conductor layers. However, electric currents necessary for electronic device have increased. For example, a 100-W grade electronic device requires a large number of pins necessary for a power supply, so these power supply pins must be formed even inside the package. Since this decreases the pin pitch, no necessary electric current can be extracted any longer from an internal conductor pattern alone, and it becomes necessary to supply an electric current from a surface conductor layer as well. In particular, no electric current can be extracted from inside the package.

Accordingly, an electric current is recently extracted by forming a surface conductor layer on a printed circuit board.

As described in, e.g., Jpn. Pat. Appln. KOKAI Publication No. 2005-12088, however, a recent electronic device has a lid on the package in order to radiate 100-W grade heat. Therefore, even when a printed wiring board and electronic part are heated during assembly, the lid absorbs the heat, so it takes a long time to melt solder. Also, it is necessary, during the heating, to raise the temperature until all solder balls of the package evenly melt, but this even melting is difficult to control.

Heating and melting of solder balls depend upon heat conduction by the convection of air in a heating apparatus, and heat conduction of the conductor. By heat conduction by the convection of air, solder balls formed on the outer periphery of the package melt fast, and solder balls formed inside those solder balls do not easily melt. By heat conduction of the conductor, a solder ball on a ground power supply electrode melts slowly because it is separated from a surface conductor layer, and a solder ball on a power supply voltage electrode melts fast because it is integrated with the surface conductor layer. In a printed circuit board having a surface conductor layer, therefore, melting variations of solder balls as described above readily form a solder bridge which is a phenomenon in which an excessively melted solder ball extends to an adjacent solder ball to short circuit the electrodes.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a view for explaining an example of the arrangement of a pad and surface conductor layer used in the present invention;

FIG. 2 is a view for explaining another example of the arrangement of a pad and surface conductor layer used in the present invention;

FIG. 3 is a view for explaining still another example of the arrangement of a pad and surface conductor layer used in the present invention;

FIG. 4 is a view for explaining still another example of the arrangement of a pad and surface conductor layer used in the present invention;

FIG. 5 is a view for explaining an example of the arrangement of a plurality of pads on which a ball grid array package is to be mounted and a surface conductor layer;

FIG. 6 is a schematic sectional view for explaining an example of a printed wiring board according to the present invention;

FIG. 7 is a view for explaining the arrangement of a conductor in a via hole and an internal conductor pattern;

FIG. 8 is a view showing a part of a process of mounting a ball grid arrange package on the printed wiring board; and

FIG. 9 is a schematic sectional view for explaining an example of a printed circuit board according to the present invention.

### DETAILED DESCRIPTION

Various embodiments according to the invention will be described hereinafter with reference to the accompanying drawings. In general, according to one embodiment of the invention, a printed wiring board of the present invention comprises a substrate, a plurality of pads formed on the substrate, a surface conductor layer formed around the pads, and a solder resist layer formed to expose at least portions of the pads on the substrate on which the pads and the surface conductor layer are formed, wherein at least one of the plurality of pads is partially in contact with the surface conductor layer.

Since the printed wiring board of the present invention has the surface conductor layer, it is possible to use not only heat transfer by the convection of air but also heat transfer by the surface conductor layer during soldering. Therefore, solder balls can be efficiently melted. Also, at least one of the pads used in the present invention is partially in contact with the surface conductor layer. When this pad is formed in a portion where a solder ball is easy to excessively melt, heat conduction to the pad is suppressed. Accordingly, when the printed wiring board is connected to a ball grid package, it is possible to reduce variations in melting of solder balls and prevent the formation of a solder bridge.

The arrangement of a plurality of pads and a surface conductor layer used in the present invention will be explained below with reference to the views of the accompanying drawing.

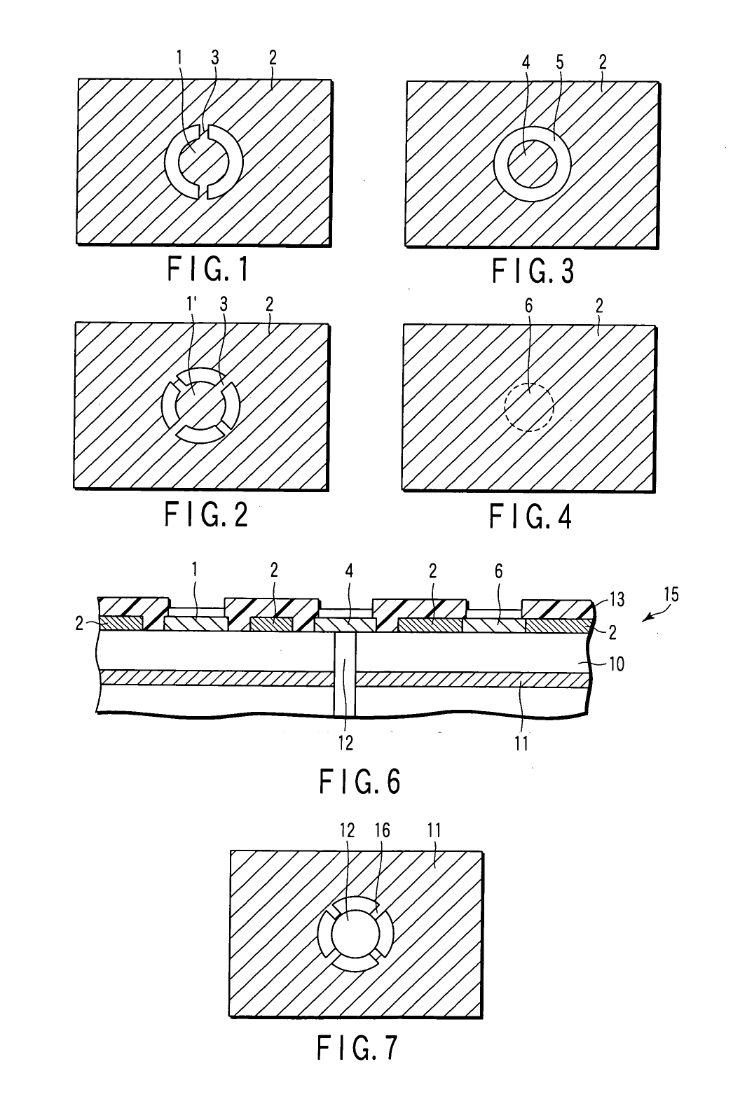

FIG. 1 is a view for explaining an example of the arrangement of a pad and surface conductor layer used in the present invention. FIG. 2 is a view for explaining another example of the arrangement. FIG. 3 is a view for explaining still another example of the arrangement. FIG. 4 is a view for explaining still another example of the arrangement.

In the arrangements shown in FIGS. 1 and 2, power supply voltage electrode pads 1 and 1′ are partially in contact with a surface conductor layer 2 having an equal potential in contact portions 3. When the power supply voltage electrode pad 1 and surface conductor layer 2 are made of the same material such as copper, they can be formed in the same step by plating by using a mask. In the arrangement shown in FIG. 1, the shape of the obtained copper plating layer has a structure in which the substantially circular power supply voltage electrode pad 1 and the surface conductor layer 2 formed around it are separated except in the two contact portions 3 each extending by a predetermined width from the pad 1 on an extended line along the diameter of the pad 1. In the arrangement shown in FIG. 2, the shape of the obtained copper plating layer has a structure in which the power supply voltage electrode pad 1 and the surface conductor layer 2 formed around it are separated except in the two contact portions shown in FIG. 1 and in the two contact portions 3 each extending by a predetermined width on that extended line along the diameter, which is perpendicular to the extended line connecting the former contact portions.

In the arrangement shown in FIG. 3, a ground power supply voltage pad 4 is completely separated from a surface conductor layer 2 having a different potential. When the pad 4 and surface conductor layer 2 are to be formed by the same material, they can be formed in the same step by plating by using a mask. The shape of the obtained plating layer has a structure in which a portion between the pad 4 and the surface conductor layer 2 is removed.

In the arrangement shown in FIG. 4, a power supply voltage electrode pad 6 is substantially integrated with a surface conductor layer 2 having an equal potential. When the pad 6 and surface conductor layer 2 are to be formed by the same material, they can be formed in the same step by plating by using a mask. As a consequence, a uniform plating layer can be obtained.

Those portions of the pads 1 and 1′ shown in FIGS. 1 and 2, which are in contact with the surface conductor layer 2 are smaller than that of the pad 6 shown in FIG. 4, so heat conduction from the surface conductor layer 2 is slow.

In the printed wiring board of the present invention, the pad 1 as described above can be formed in a portion where a solder ball which can be connected on the pad 1 is easy to excessively melt. When the printed wiring board is connected to a ball grid package, therefore, variations in melting of solder balls can be reduced.

Also, the pad 4 shown in FIG. 3 is not in contact with the surface conductor layer 2, so no heat is directly conducted from the surface conductor layer 2.

On the printed wiring board of the present invention, it is possible to form the plurality of pads 1, 1′, 4, and 6 having the shapes as shown in FIGS. 1 to 4 and the surface conductor layer 2.

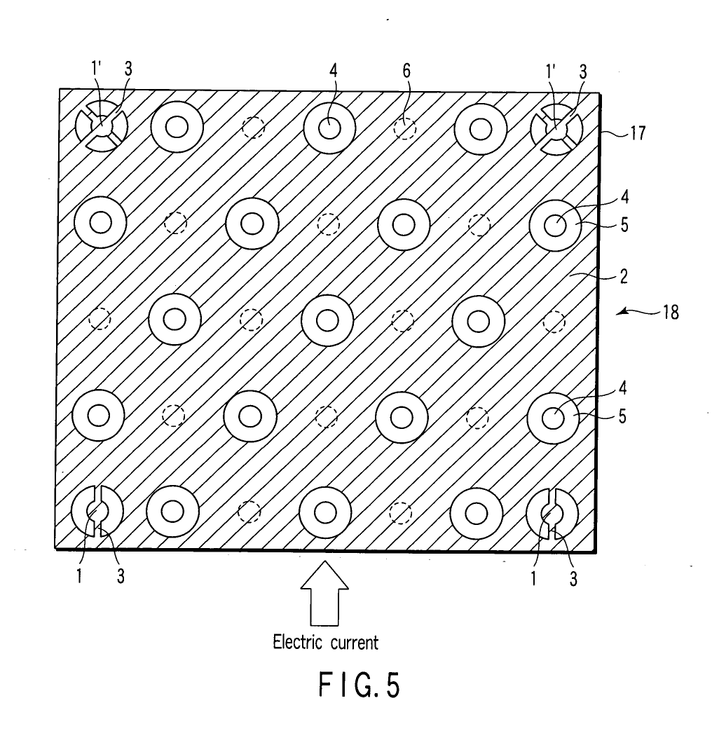

FIG. 5 shows an example of the arrangement of a plurality of pads arranged to mount a ball grid array package and a surface conductor layer.

As shown in FIG. 5, on a printed wiring board 18, a surface conductor layer 2 and a plurality of pads 1, 1′, 4, and 6 are arranged at pitches within a predetermined range. A frame 17 indicates a position corresponding to the outer periphery of a ball grid array package to be mounted. At positions corresponding to the four corners of the ball grid array package, the pads 1 and 1′ are partially in contact with the surface conductor layer 2 in contact portions 3. The pads 4 and 6 are arranged in the rest of the board.

Also, the contact portions 3 can be formed along a direction in which an electric current flows, as in, e.g., the pad 1. This can reduce the disturbance to an electric current during an operation.

FIG. 6 is a schematic sectional view for explaining an example of a printed wiring board according to the present invention.

As shown in FIG. 6, a printed wiring board 15 comprises a power supply voltage electrode pad 1, ground power supply voltage pad 4, power supply voltage electrode pad 6, and solder resist layer 13 on the surface of a substrate 10 having an internal conductor pattern 11 such as a ground interconnection made of, e.g., copper and a via hole 12 which extracts the internal conductor pattern 11 to the surface and has a diameter of, e.g., 0.25 mm. The power supply voltage electrode pad 1 made of, e.g., copper is partially in contact with a surface conductor layer 2 made of, e.g., copper in a contact portion (not shown). The ground power supply voltage pad 4 made of, e.g., copper is electrically connected to the internal conductor pattern 11, formed on the via hole 12 plated with, e.g., copper, and separated from the surface conductor layer 2. The power supply voltage electrode pad 6 is integrated with the surface conductor layer 2. The solder resist layer 13 covers the substrate on which the surface conductor layer 2 is formed, so as to expose at least potions of the pads 1, 4, and 6.

The printed wiring board 15 has a plurality of pads, and at least one of them is the pad 1 partially in contact with the surface conductor layer.

The ground power supply voltage pad 4 is separated from the surface conductor layer 2 as shown in, e.g., FIG. 3, but connected to the internal conductor pattern 11 via the via hole 12. Therefore, heat conduction from the internal conductor pattern 1 can be used to melt solder balls.

FIG. 7 is a view for explaining an example of the arrangement of the via hole and internal conductor pattern.

As shown in FIG. 7, to reduce heat conduction from the internal conductor pattern 11, a conductor (not shown) in the via hole 12 and the internal conductor pattern 11 can be partially brought into contact with each other via contact portions 16.

A ball grid array package having a plurality of solder balls can be mounted on the printed wiring board 15.

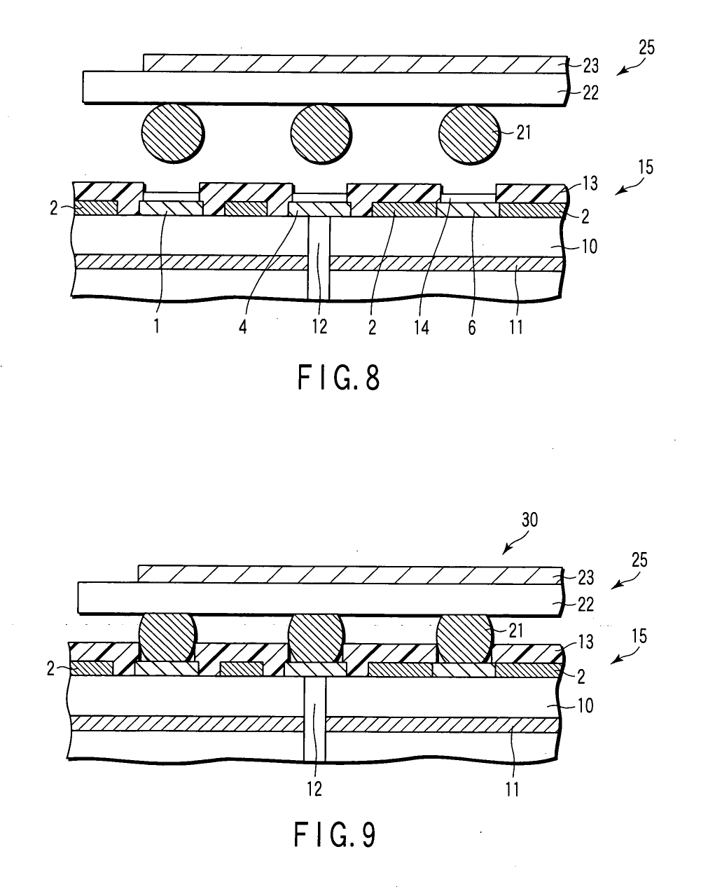

FIG. 8 is a view showing a part of a process of mounting the ball grid array package on the printed wiring board.

First, a solder paste layer 13 can be formed on the pads 1, 4, and 6 exposed from the solder resist layer 13 of the printed wiring board 15. A ball grid array package 25 having a plurality of solder balls 21 on one surface of a package main body 22 and a metal lid 23 on the other surface is prepared. The solder balls 21 and the pads 1, 4, and 6 can be aligned with each other via the solder paste layer 13.

After that, the printed wiring board 15 and ball grid array package 25 thus aligned are soldered in a heating ambient at a temperature at which the solder balls start melting or higher.

FIG. 9 is a schematic sectional view for explaining an example of a printed circuit board according to the present invention.

As shown in FIG. 9, a printed circuit board 30 has a connecting structure in which a ball grid array package 25 having the same arrangement as the ball grid array package shown in FIG. 8 is mounted on a printed wiring board 15 having the same arrangement as the printed wiring board shown in FIG. 6. The printed wiring board 15 has an array of 35×35 pads formed at a pitch of, e.g., 1 mm and including pads 1, 4, and 6. The ball grid array package 25 has a size of, e.g., 40 mm and 40 mm, and has an array of a plurality of solder balls 21 corresponding to the array of the plurality of pads. The ball grid array package 25 is soldered onto the printed wiring board 15 via the solder balls 21.

Heat conduction to the solder balls has variations in the outer peripheral region and internal region of the package.

At least one pad of the pad array used can be partially brought into contact with the surface conductor layer. The variations in melting of the solder balls can be suppressed by forming this pad in a portion where the solder ball is easy to excessively melt.

In one embodiment of the invention, the pad 1 partially in contact with the surface conductor layer can be formed as at least one of the pads positioned in the four corners where the solder balls are particularly easy to excessively melt. This makes it possible to effectively suppress the variations in melting of the solder balls.

In some embodiment of the invention, the pad 1 partially in contact with the surface conductor layer can be formed in at least one row of the outer peripheral region of the ball grid array package 25. This makes it possible to more effectively suppress the variations in melting of the solder balls.

For example, pads partially in contact with a surface conductor layer were formed in the corners of 5×5 pins and soldered to a ball grid array package, and the presence/absence of a solder bridge of the obtained printed circuit board was checked by a conduction test and X-ray image. Consequently, no solder bridge was found even after 60 printed circuit boards were formed.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed wiring board comprising a substrate, a plurality of pads formed on the substrate, a surface conductor layer formed around the pads, and a solder resist layer formed to expose at least portions of the pads on the substrate on which the pads and the surface conductor layer are formed,
wherein at least one of said plurality of pads is partially in contact with the surface conductor layer.

2. A board according to claim 1, wherein the substrate comprises an internal conductor pattern, and a via hole including a conductor pattern for extracting the internal conductor pattern to a substrate surface, and the conductor in the via hole and the internal conductor pattern are entirely in contact with each other.

3. A board according to claim 1, further comprising a plurality of pads arranged to mount a ball grid array package comprising a plurality of solder balls,
wherein at least one of pads positioned in corners of the ball grid array package is partially in contact with the surface conductor layer.

4. A board according to claim 3, wherein in a portion of at least one row of a plurality of pads positioned in an outer peripheral region, said each pad and the surface conductor layer are partially in contact with each other.

5. A board according to claim 1, wherein a contact portion of the pad and the surface conductor layer is formed along a direction in which an electric current flows.

6. A printed circuit board comprising a packaging structure in which a printed wiring board comprising a substrate, a plurality of pads formed on the substrate, a surface conductor layer formed around the pads, and a solder resist layer formed to expose at least portions of the pads on the substrate on which the pads and the surface conductor layer are formed and a ball grid array package comprising a plurality of solder balls are connected by melting the solder balls on the pads,
wherein at least one of said plurality of pads is partially in contact with the surface conductor layer.

7. A board according to claim 6, wherein the substrate comprises an internal conductor pattern, and a via hole including a conductor pattern for extracting the internal conductor pattern to a substrate surface, and the conductor in the via hole and the internal conductor pattern are entirely in contact with each other.

8. A board according to claim 6, wherein at least one of pads positioned in corners of an outer peripheral region of the ball grid array package is partially in contact with the surface conductor layer.

9. A board according to claim 8, wherein a portion of at least one row of pads positioned in the outer peripheral region is partially in contact with the surface conductor layer.

10. A board according to claim 6, wherein a contact portion of the pad and the surface conductor layer is formed along a direction in which an electric current flows.
